(19) United States
(12) Patent Application Publication
(10) Pub. No.: US 2004/0152305 A1
(43) Pub. Date: Aug. 5, 2004

(54) METHOD FOR PREVENTING CORROSION OF TUNGSTEN PLUG

(76) Inventors: CHUNG-LUNG YIU, HSINCHU (TW); SZU-TSUN MA, HSINCHU (TW); KENT KUOHUA CHANG, TAIPEI (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/248,574

(22) Filed: Jan. 30, 2003

(51) Int. Cl. H01L 21/44

(52) U.S. Cl. 438/685

(57) ABSTRACT

A method of preventing the corrosion of tungsten plug within a substrate in the process of manufacturing a semiconductor device. The tungsten plug within the substrate is coupled to a conductive line on the substrate. The process includes treating the substrate with a charge neutralizer so that charges accumulated on the surface of the conductive line during etching is removed and conducting a wet-cleaning operation thereafter.

### BACKGROUND OF INVENTION

1. Field of Invention

The present invention relates to a semiconductor fabrication process. More particularly, the present invention relates to a method for preventing the corrosion of a tungsten plug.

2. Description of Related Art

Through the miniaturization of line width in semiconductor devices and circuits, high-speed, low power rating, multi-functional ultra-high level integrated circuit chips are produced en-mass. Due to the miniaturization and integration of semiconductor devices, interconnecting lines has to increase so much that the surface of a chip is hardly able to accommodate them all. To deal with this problem, a multi-layered interconnect design is routinely employed in the fabrication of integrated circuits.

In the fabrication of multi-layered interconnects, another layer of metallic line is formed after the fabrication of a tungsten plug is completed. If the size of a device is large, the conductive line will completely cover the underlying tungsten plug. Hence, tungsten plug corrosion problem occurs only when the stepper in a photolithographic process produces some alignment errors causing the patterned conductive layer to shift from the supposed location on top of the tungsten plug. However, as the dimension of each device is reduced, the probability of misalignment between a conductive layer and an underlying tungsten plug increases considerably. Therefore, the corrosion of the tungsten plug and its overlying conductive layer has gradually emerged as an important issue in the manufacturing of integrated circuits.

FIGS. 1A and 1B are schematic cross-sectional views showing the steps for fabricating a conventional metallic interconnect. The structure in FIG. 1A includes a substrate 100, an inter-layer dielectric 102, an adhesion layer 104, a tungsten plug 106, a metallic line 108 and a patterned photoresist layer 110. The adhesion layer 104 is fabricated using a material such as titanium nitride, tungsten-titanium or other barrier material. As shown in FIG. 1A, the conductive line 108 covers only a portion of the tungsten plug 106. The reason for such partial coverage results from a misalignment of the pattern for forming the conductive line 108 relative to the plug 106 or a desire to utilize chip area more efficiently.

As shown in FIG. 1B, the patterned photoresist layer 110 is ashed using oxygen plasma. Thereafter, a stripping solution (for example, EKC-265TM provided by EKC technology company) having a pH value between 10 to 12 is used to remove any remaining photoresist material and residual polymer residue. Since the conductive line 108 is not perfectly aligned with the tungsten plug 106, a portion of the exposed tungsten plug 106 will be corroded by the stripping solution to form a cavity 112. Tungsten is easily corroded mainly due to the accumulation of positive electric charges (“+”) on the surface of the conductive line 108 when the conductive line 108 is patterned by etching or the photoresist layer 110 is ashed by oxygen plasma. Hence, a significant electrochemical potential is established between the electrically charged conductive line 108 and the tungsten plug 106 (two metallic layer having a different electrochemical potential will produce a galvanic couple. When the stripping solution having a pH value between 10 to 12 is used as an agent for wet cleaning, the exposed tungsten is oxidized into tungsten oxide ions (for example, WO₄⁻²). These tungsten ions are removed in subsequent cleansing operations leading to the formation of the cavity 112 within the tungsten plug 106. Due to corrosion of the tungsten plug 106, contact area between the tungsten plug 106 and the patterned conductive line 108 will be reduced and hence resistance of the conductive line 108 will be increased. Ultimately, the integrated circuit may fail.

One method of tackling the corrosion problem is to immerse the substrate into a tank of neutral solution (such as an electrolyte) or de-ionized water for a few hours and then conduct a wet cleaning process using a stripping solution. Immersing the substrate in a pool of neutral ionic solution is able to strip away any accumulated charges from the surface of the conductive line. Although this method is able to prevent electrochemical corrosion of the tungsten plug, this will lead to the corrosion of the overlying conductive line (the metal within the conductive line may react with salt or electrolyte within the ionic solution). Furthermore, in the conventional method of using a neutral solution (such as an electrolyte) or de-ionized water to treat the substrate, a very long processing time is required. Aside from the substrate immersion step, extra cleaning/drying steps has to be introduced in order to remove any residual solution (salt/electrolyte solution) from the substrate. Thus, the conventional processing method is long and costly.

### SUMMARY OF INVENTION

Accordingly, one object of the present invention is to provide a method capable of preventing the corrosion of tungsten plug during a semiconductor fabrication process. First, a substrate with a tungsten plug and a conductive line coupled to the tungsten plug is provided. Using a charge neutralizer, the substrate is treated for a period between 3 andto 65 minutes to remove any charges attached to the surface of the conductive line. Finally, a conventional wet cleaning of the substrate is carried out.

In this invention, a charge neutralizer (ionizer) is used to remove charges accumulated on the conductive line and thus prevent electrochemical corrosion of the tungsten plug. Once the accumulated charges on the conductive line are removed, electrochemical potential between the tungsten plug and the conductive line during subsequent wet cleaning step will be reduced considerably. Since the tungsten within the plug no longer oxidizes, corrosion of the plug is prevented. Furthermore, treating the substrate with a neutralizer will not corrode the interconnecting line pattern over the tungsten plug.

This invention also provides a method of fabricating semiconductor device. A substrate having a tungsten plug thereon is provided. A metallic layer and a patterned photoresist layer are sequentially formed over the substrate. Thereafter, using the patterned photoresist layer as a mask, the metallic layer is etched to form a conductive line. The conductive line covers a portion of the tungsten plug. The substrate is treated using a charge neutralizer for a period between 3 andto 65 minutes. Finally, the patterned photoresist layer is removed.

After etching the metallic layer, the substrate is treated using a charge neutralizer to remove any charges accumulated on the surface of the conductive line and the patterned photoresist layer. Therefore, the exposed section of the tungsten plug is prevented from oxidation and removal when the patterned photoresist layer is subsequently removed. Furthermore, treating the substrate with a neutralizer will not corrode the interconnecting line pattern over the tungsten plug.

This invention also provides a second method of fabricating semiconductor device. A substrate having a tungsten plug thereon is provided. A metallic layer and a patterned photoresist layer are sequentially formed over the substrate. Thereafter, using the patterned photoresist layer as a mask, the metallic layer is etched to form a conductive line. The conductive line covers a portion of the tungsten plug. The patterned photoresist layer is ashed using oxygen plasma. The substrate is treated using a charge neutralizer for a period between 3 andto 65 minutes to remove any charges attached to the conductive line. Finally, a wet cleaning step is carried out to remove any residual photoresist material and polymer attached to the surface of the substrate.

After forming the conductive line and ashing the patterned photoresist layer using oxygen plasma, the substrate is treated using a charge neutralizer to remove any charges accumulated on the surface of the conductive line. Therefore, the exposed section of the tungsten plug is prevented from oxidation and removal in the subsequent wet cleaning step. Furthermore, treating the substrate with a neutralizer will not corrode the interconnecting line pattern over the tungsten plug.

In addition, the charge neutralizer (ionizer) is typically installed within a wafer loading/unloading region or inside an individualindependent nitrogen storage chamber inside an etching station. After etching the metallic layer, the wafer can be transferred to the wafer loading/unloading region or the individual independent nitrogen storage chamber to be processed by the neutralizer for a few minutes. With accumulated charges on the surface of the conductive line and the patterned photoresist layer removed, subsequent corrosion of the tungsten plug is prevented. Thus, the process according to this invention simplifies the steps for fabricating a metallic layer and saves production cost of semiconductor devices. Moreover, there is no need to replace existing processing equipment or to purchase expensive additional equipment and the processing steps generate very little contaminants.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A and 1B are schematic cross-sectional views showing the steps for fabricating a conventional metallic interconnect; and

FIGS. 2A to 2D are schematic cross-sectional view showing the progression of steps for fabricating an metallic interconnect according to one preferred embodiment of this invention.

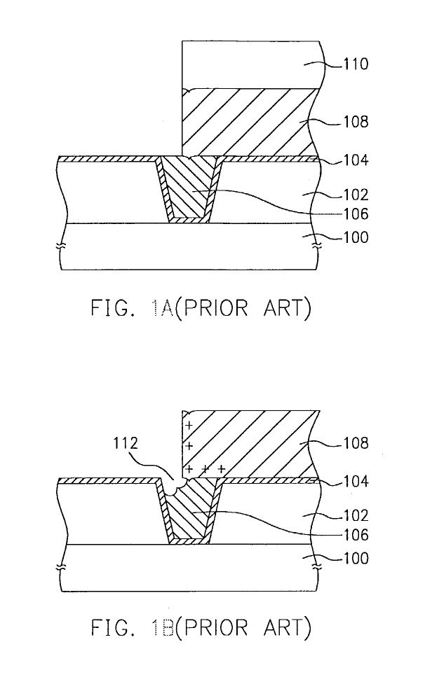

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

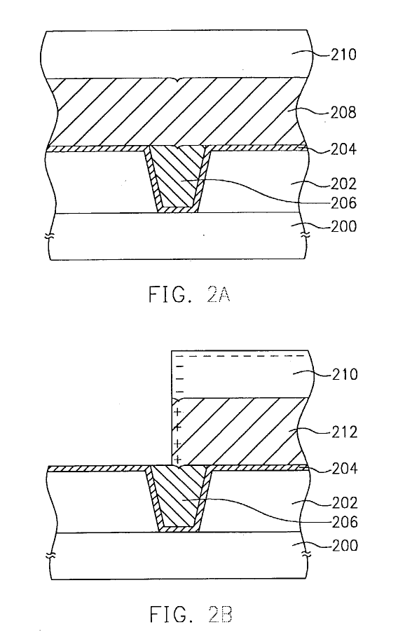

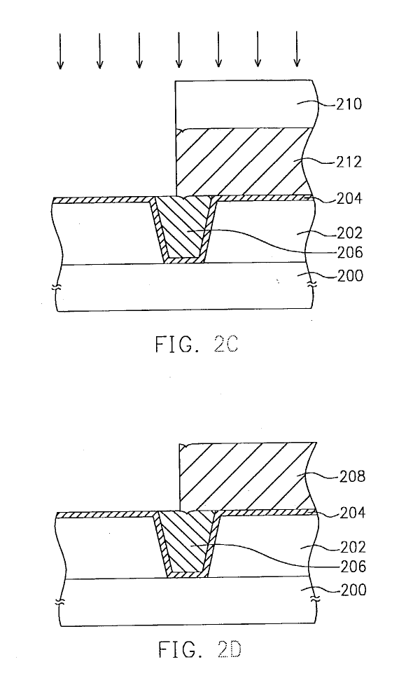

FIGS. 2A to 2D are schematic cross-sectional view showing the progression of steps for fabricating an metallic interconnect according to one preferred embodiment of this invention. As shown in FIG. 2A, a substrate 200 having an inter-layer dielectric 202 thereon is provided. An adhesion layer 204 and a tungsten plug 206 are formed in the inter-layer dielectric 202. Obviously, the substrate 200 may also include other devices or metallic lines. These other devices or metallic lines are not drawn out to simplify the figure. Thereafter, a metallic layer 208 and a patterned photoresist layer 210 are sequentially formed over the substrate 200. The metallic layer is fabricated using material such as an alloy of aluminum, copper or an alloy of copper.

As shown in FIG. 2B, the substrate 200 is placed inside an etcher. Using the patterned photoresist layer 210 as a mask, a portion of the metallic layer 208 is removed to expose the inter-layer dielectric 202 and form a conductive line 212. The etcher is a dry etcher, for example. The conductive line 212 formed by the etching step covers only a portion of the underlying tungsten plug 206 according to the 0.18 μ m design rule (or smaller design rule). After etching the metallic layer 208, negative charges may accumulate on the surface of the patterned photoresist layer 210 and positive charges may accumulate on the surface of the conductive line 212. The presence of charges on the conductive line 212 may lead to subsequent corrosion of the tungsten plug 206.

As shown in FIG. 2C, the substrate 200 is transferred from the etcher to a nitrogen storage chamber with a charge neutralizer installed therein. The nitrogen storage chamber is located, for example, in the wafer loading/unloading area of the etcher. Obviously, the nitrogen storage chamber can be a compartment detached from the etcher. Inside the nitrogen storage chamber, the substrate 200 with the tungsten plug 206, the conductive line 212 and patterned photoresist layer 210 thereon is treated by the charge neutralizer such as an ionizer for a period between 3 andto 65 minutes. After the treatment, charges accumulated on the surface of the conductive line 212 and the patterned photoresist layer 210 is cleared. Aside from reducing accumulated charges on the tungsten plug 206 or the conductive line 212, the charge neutralizer also prevents surface corrosion of the tungsten plug 206 and the conductive line 212 due to an electrochemical potential.

As shown in FIG. 2D, the substrate 200 is transferred from the nitrogen storage chamber to a reaction chamber. Thereafter, oxygen plasma is used to ash the patterned photoresist layer 210. The substrate 200 is transferred from the reaction chamber to a cleaning device to wet-clean the substrate 200. The wet cleaning step serves to remove any residual photoresist material or polymer compound on the substrate 200. Finally, other processes necessary for completing the semiconductor fabrication are carried out. Since only conventional processes are used, detail description is omitted here.

According to the embodiment of this invention, a charge neutralizer is used to treat the substrate after the metal etching step. The neutralizer removes accumulated charges on the surface of both the conductive line and the patterned photoresist layer so that the exposed tungsten plug is prevented from oxidation and removal during subsequent wet cleaning. The removal of charges from the surface of the conductive line also prevents the corrosion of the conductive line.

Furthermore, the charge neutralizer (ionizer) is directly installed inside the wafer loading/unloading region of the etcher or an individual independent nitrogen storage chamber. Thus, the wafer can be transferred to the charge neutralizer to conduct a few minutes of treatment inside the wafer loading/unloading region or the stand-alone nitrogen storage chamber after metal etching. Consequently, charges accumulated on the surface of the conductive line and the patterned photoresist layer can be removed without installing expensive additional equipment.

In the aforementioned embodiment, the charge-neutralizing treatment is carried out after metal etching. Obviously, to prevent the corrosion of the tungsten plug, the charge-neutralizing treatment may be carried out after oxygen plasma ashing of the photoresist layer but before the wet cleaning step.

Since the charge neutralizer (ionizer) is installed in the wafer loading/unloading region or a stand-alone nitrogen storage chamber inside the etcher, expensive equipment is not required. Moreover, the charge neutralizer requires only a few minutes to clear up the accumulated charges produced in the metal etching process. This prevents the corrosion of the tungsten plug during a subsequent cleaning operation and hence reduces the probability of having an open circuit condition.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A method of preventing the corrosion of tungsten plug, comprising the steps of:
providing a substrate having a tungsten plug therein, wherein the tungsten plug couples with a conductive line on the substrate;
treating the substrate with a charge neutralizer; and
wet-cleaning the substrate.

2. The method of claim 1, wherein charge neutralizer is an effective device for removing charges accumulated on the surface of the conductive line.

3. The method of claim 1, wherein the charge neutralizer includes an ionizer.

4. The method of claim 1, wherein the step of treating the substrate includes operating the charge neutralizer for a period between 3 andto 65 minutes.

5. The method of claim 1, wherein the conductive line is fabricated using an alloy of aluminum.

6. The method of claim 1, wherein the conductive line is fabricated using copper or an alloy of copper.

7. The method of claim 1, wherein the charge neutralizer is installed inside a wafer loading/unloading region of an etcher.

8. The method of claim 1, wherein the charge neutralizer is installed inside an individual nitrogen storage chamber.

9. A method of fabricating a semiconductor device, comprising the steps of:
providing a substrate having a tungsten plug therein;
forming a metallic layer over the substrate;
forming a patterned photoresist layer over the metallic layer;
etching the metallic layer to form a conductive line using the patterned photoresist layer as a mask such that the conductive line covers the tungsten plug only partially;
treating the substrate with a charge neutralizer; and removing the patterned photoresist layer.

10. The method of claim 9, wherein the charge neutralizer is a device for removing accumulated charges on the surface of the conductive line and the patterned photoresist layer.

11. The method of claim 9, wherein the charge neutralizer includes an ionizer.

12. The method of claim 9, wherein the step of treating the substrate includes operating the charge neutralizer for a period between 3 andto 65 minutes.

13. The method of claim 9, wherein the conductive line is fabricated using an alloy of aluminum.

14. The method of claim 9, wherein the conductive line is fabricated using copper or an alloy of copper.

15. The method of claim 9, wherein the charge neutralizer is installed inside a wafer loading/unloading region of an etcher.

16. The method of claim 9, wherein the charge neutralizer is installed inside an individual nitrogen storage chamber.

17. The method of claim 9, wherein the step of removing the patterned photoresist layer includes the sub-steps of:
ashing the patterned photoresist layer with oxygen plasma; and
wet-cleaning the substrate to remove any residual photoresist material and polymer compound on the surface of the substrate.

18. A method of fabricating metallic interconnect, comprising the steps of:
providing a substrate having tungsten plug therein;
forming a metallic layer over the substrate;
forming a patterned photoresist layer over the metallic layer;
etching the metallic layer to form a conductive line using the patterned photoresist layer as a mask such that the conductive line covers only a portion of the tungsten plug;
ashing the patterned photoresist layer with oxygen plasma;
treating the substrate with a charge neutralizer; and
wet-cleaning the substrate.

19. The method of claim 18, wherein the charge neutralizer is a device for removing accumulated charges on the surface of the conductive line and the patterned photoresist layer.

20. The method of claim 18, wherein the charge neutralizer includes an ionizer.

21. The method of claim 18, wherein the step of treating the substrate includes operating the charge neutralizer for a period between 3 andto 65 minutes.

22. The method of claim 18, wherein the conductive line is fabricated using an alloy of aluminum.

23. The method of claim 18, wherein the conductive line is fabricated using copper or an alloy of copper.

24. The method of claim 18, wherein the charge neutralizer is installed inside a wafer loading/unloading region of an etcher.

25. The method of claim 18, wherein the charge neutralizer is installed inside an individual nitrogen storage chamber.
